(19) United States
(12) Patent Application Publication
(10) Pub. No.: US 2025/0393124 A1
(43) Pub. Date: Dec. 25, 2025

(54) PRINTED WIRING BOARD

(71) Applicant: IBIDEN CO., LTD., Ogaki (JP)

(72) Inventors: Ryo ANDO, Ogaki (JP); Yuto TAMURA, Ogaki (JP)

(73) Assignee: IBIDEN CO., LTD., Ogaki (JP)

(21) Appl. No.: 19/248,168

(22) Filed: Jun. 24, 2025

(30) Foreign Application Priority Data
Jun. 25, 2024 (JP) 2024-102086

(51) Int. Cl. H05K 1/11; H05K 3/18

(52) U.S. Cl. CPC H05K 1/116; H05K 3/188; H05K 2201/0338; H05K 2201/0358; H05K 2203/0315; H05K 2203/0723

(57) ABSTRACT

A printed wiring board includes an insulating layer, a conductor layer formed on the insulating layer, an adhesive layer formed on the conductor layer, and a resin insulating layer formed on the insulating layer such that the resin insulating layer is covering the conductor layer. The conductor layer includes a main component including copper such that the conductor layer includes a copper oxide film forming a surface thereof.

### CROSS-REFERENCE TO RELATED APPLICATIONS

The present application is based upon and claims the benefit of priority to Japanese Patent Application No. 2024-102086, filed Jun. 25, 2024, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2001-203462 describes a method for manufacturing a multilayer printed wiring board. The entire contents of this publication are incorporated herein by reference.

### SUMMARY OF THE INVENTION

According to one aspect of the present invention, a printed wiring board includes an insulating layer, a conductor layer formed on the insulating layer, an adhesive layer formed on the conductor layer, and a resin insulating layer formed on the insulating layer such that the resin insulating layer is covering the conductor layer. The conductor layer includes a main component including copper such that the conductor layer includes a copper oxide film forming a surface thereof.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2 is an enlarged cross-sectional view schematically illustrating a part of the printed wiring board;

FIG. 3A is a cross-sectional view schematically illustrating a method for manufacturing a printed wiring board according to an embodiment of the present invention;

FIG. 3B is a cross-sectional view schematically illustrating a method for manufacturing a printed wiring board according to an embodiment of the present invention;

FIG. 3C is a cross-sectional view schematically illustrating a method for manufacturing a printed wiring board according to an embodiment of the present invention;

FIG. 3D is a cross-sectional view schematically illustrating a method for manufacturing a printed wiring board according to an embodiment of the present invention; and

FIG. 3E is a cross-sectional view schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

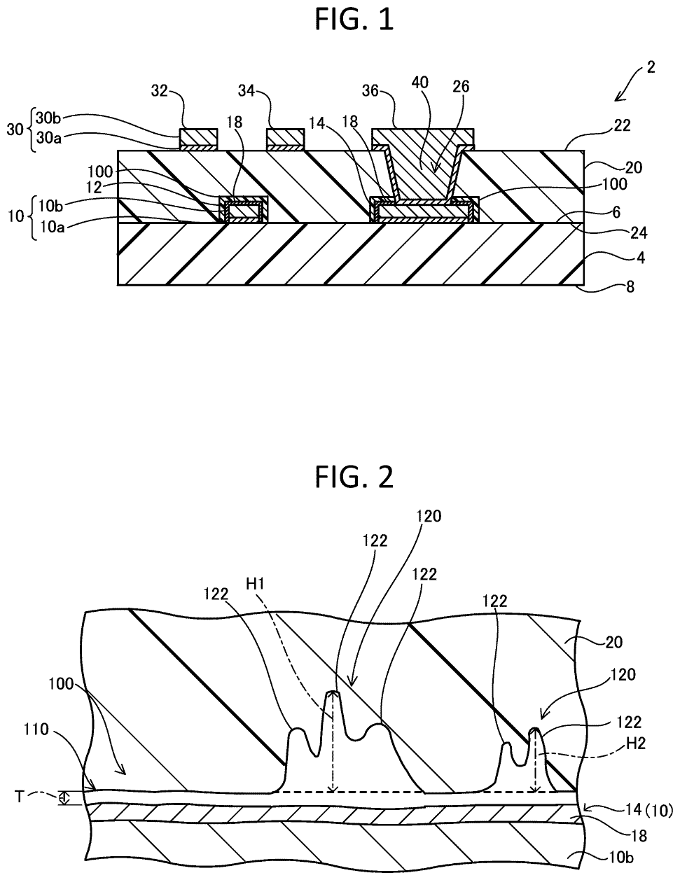

FIG. 1 is a cross-sectional view illustrating a printed wiring board 2 of an embodiment. As illustrated in FIG. 1, the printed wiring board 2 includes an insulating layer 4, a first conductor layer 10, a resin insulating layer 20, a second conductor layer 30, and a via conductor 40. The via conductor 40 is formed in an opening 26 that penetrates the resin insulating layer 20 and exposes the first conductor layer 10. The printed wiring board 2 has an adhesive layer 100 on the first conductor layer 10. The adhesive layer 100 is sandwiched between the first conductor layer 10 and the resin insulating layer 20. The first conductor layer 10 and the second conductor layer 30 are adjacent to each other. There is no conductor layer between the first conductor layer 10 and the second conductor layer 30.

The insulating layer 4 is formed using a thermosetting resin. It is also possible that the insulating layer 4 is formed of a photocurable resin. The insulating layer 4 may contain inorganic particles such as silica particles. The insulating layer 4 may contain a reinforcing material such as a glass cloth. The insulating layer 4 has a third surface 6 and a fourth surface 8 on the opposite side with respect to the third surface 6.

The first conductor layer 10 is formed on the third surface 6 of the insulating layer 4. The first conductor layer 10 includes a signal wiring 12 and a pad 14. Although not illustrated in the drawings, the first conductor layer 10 also includes conductor circuits other than the signal wiring 12 and the pad 14. The first conductor layer 10 is mainly formed of copper. The first conductor layer 10 is formed of a seed layer (10a) on the insulating layer 4 and an electrolytic plating layer (10b) on the seed layer (10a). The electrolytic plating layer (10b) is formed of an electrolytic copper plating layer. A surface (including upper and side surfaces) of the first conductor layer 10 has a rough surface. For example, the surface of the first conductor layer 10 is roughened. Since a size of the rough surface is small, the surface of the first conductor layer 10 is substantially smooth. The surface of the first conductor layer 10 has a root mean square roughness (Rq) of 0.23 μm or less. The root mean square roughness (Rq) of the surface of the first conductor layer 10 is preferably 0.1 μm or less.

The surface of the first conductor layer 10 is formed of a copper oxide film 18. The copper oxide film 18 is formed by oxidizing the surface (including upper and side surfaces) of the electrolytic plating layer (10b). The copper oxide film 18 may include a copper oxide film formed by oxidizing a side surface of the seed layer (10a). A main component of the copper oxide film 18 is Cu₂O. The copper oxide film 18 contains Cu₂O and CuO, and the Cu₂O content is 90 wt % or more. The copper oxide film 18 has a thickness of 10 nm or less. The thickness of the copper oxide film 18 is 3 nm or more.

An upper surface of a conductor circuit forming the first conductor layer 10 is formed of a first surface and a second surface. The first surface is exposed from the opening 26 and is not covered by the copper oxide film 18 and the adhesive layer 100. The second surface is a portion other than the first surface and is covered by the copper oxide film 18 and the adhesive layer 100. The side surface of the first conductor layer 10 is covered by the copper oxide film 18 and the adhesive layer 100. When the opening 26 does not reach the conductor circuit forming the first conductor layer 10, the upper surface of such a conductor circuit is formed only of the second surface. The first surface does not exist.

The adhesive layer 100 is formed of an organic material. An example of the organic material is a nitrogen-based organic compound. The nitrogen-based organic compound is, for example, a tetrazole compound. Examples of the nitrogen-based organic compound are disclosed in Japanese Patent Application Laid-Open Publication No. 2015-54987. The adhesive layer 100 does not cover the third surface 6 exposed from the first conductor layer 10. The adhesive layer 100 is sandwiched between the first conductor layer 10 and the resin insulating layer 20. The adhesive layer 100 is sandwiched between the copper oxide film 18 and the resin insulating layer 20. The adhesive layer 100 adheres the first conductor layer 10 and the resin insulating layer 20 via the copper oxide film 18. The resin insulating layer 20 is in contact with the adhesive layer 100.

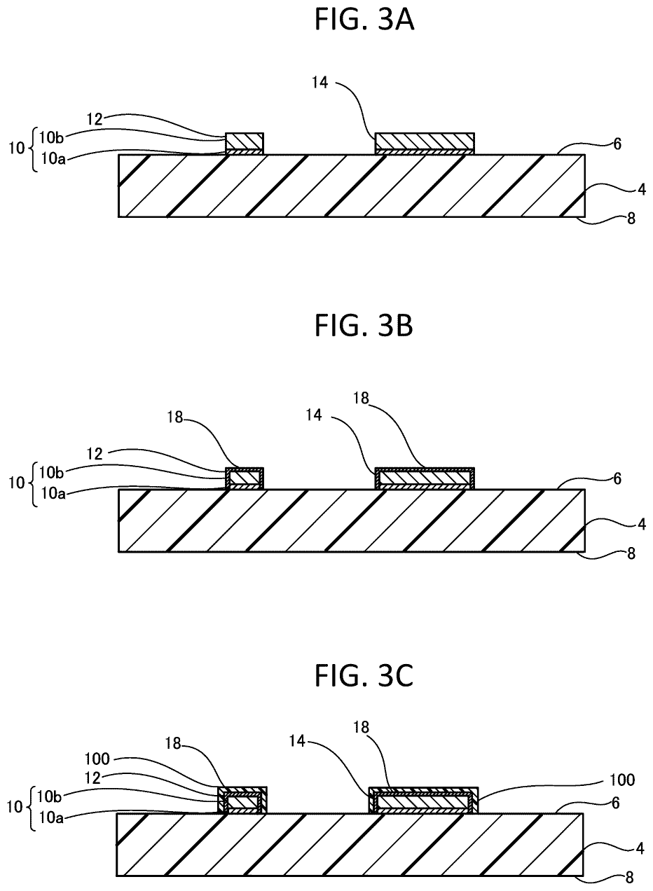

FIG. 2 is an enlarged cross-sectional view illustrating a part of the adhesive layer 100 formed on the second surface. As illustrated in FIG. 2, the adhesive layer 100 is formed of a smooth film 110, which is substantially smooth, and multiple protruding parts 120 protruding from the smooth film 110. The adhesive layer 100 formed on a side surface of the pad 14 is formed of a smooth film 110 and multiple protruding parts 120 similar to the adhesive layer illustrated in FIG. 2, and also has a similar shape. The adhesive layer 100 formed on an upper surface and a side surface of the signal wiring 12 is formed of a smooth film 110 and multiple protruding parts 120 similar to that illustrated in FIG. 2, and also has a similar shape. The adhesive layer 100 formed on the upper and side surfaces of the first conductor layer 10 has a shape similar to that illustrated in FIG. 2.

The smooth film 110 has a substantially uniform thickness (T). The thickness (T) of the smooth film 110 is 10 nm or more and 120 nm or less. A ratio (S1/S2) of an area (S1) of the smooth film 110 exposed from the protruding parts 120 to an area (S2) of the adhesive layer 100 is 0.1 or more and 0.5 or less. The smooth film 110 on the upper surface of the first conductor layer 10 is formed substantially along a shape of the upper surface of the first conductor layer 10. The smooth film 110 on the second surface of the first conductor layer 10 is formed substantially along a shape of the second surface of the first conductor layer 10. The smooth film 110 on the side surface of the first conductor layer 10 is formed substantially along a shape of the side surface of the first conductor layer 10. When undulations are formed on the upper surface and the side surface of the first conductor layer 10, the smooth film 110 follows the undulations.

The protruding parts 120 are formed of multiple protrusions 122. Due to the multiple protrusions 122, unevenness is formed on upper surfaces of the protruding parts 120. The number of the protrusions 122 per 1 mm2 is 5 or more and 15 or less. The protruding parts 120 have heights (H1, H2) between the upper surface of the smooth film 110 and top parts of the protruding parts 120. A maximum value of the heights (H1, H2) is 10 times or more and 30 times or less the thickness (T) of the smooth film 110. The heights (H1, H2) are 200 nm or more and 450 nm or less.

The resin insulating layer 20 is formed on the first conductor layer 10 via the adhesive layer 100. The resin insulating layer 20 is adhered to the first conductor layer 10 by the adhesive layer 100. The rough surfaces formed on the upper and side surfaces of the first conductor layer 10 contribute to the adhesion between the resin insulating layer 20 and the first conductor layer 10. The resin insulating layer 20 has a first surface 22 and a second surface 24 on the opposite side with respect to the first surface 22. The second surface 24 of the resin insulating layer 20 faces the first conductor layer 10. The second surface 24 is in contact with the adhesive layer 100. The resin insulating layer 20 has the opening 26 that exposes the pad 14. The resin insulating layer 20 is formed of an epoxy resin and inorganic particles dispersed in the epoxy resin. Examples of the resin include a thermosetting resin and a photocurable resin. Examples of the inorganic particles include silica particles and alumina particles. An amount of the inorganic particles in the resin insulating layer 20 is 70 wt % or more.

The first surface 22 of the resin insulating layer 20 has no unevenness. The first surface 22 is not roughened. The first surface 22 is formed smooth. A thickness of the resin insulating layer 20 is two or more times a thickness of the second conductor layer 30. The thickness of the resin insulating layer 20 is a distance between the first surface 22 and the upper surface of the first conductor layer 10.

The second conductor layer 30 is formed on the first surface 22 of the resin insulating layer 20. The second conductor layer 30 includes a first signal wiring 32, a second signal wiring 34, and a land 36. Although not illustrated in the drawings, the second conductor layer 30 also includes conductor circuits other than the first signal wiring 32, the second signal wiring 34, and the land 36. The first signal wiring 32 and the second signal wiring 34 form a pair wiring. The second conductor layer 30 is mainly formed of copper. The second conductor layer 30 is formed of a seed layer (30a) on the first surface 22 and an electrolytic plating layer (30b) on the seed layer (30a).

The via conductor 40 is formed in the opening 26. The opening 26 exposes the electrolytic plating layer (10b) of the pad 14. The via conductor 40 connects the electrolytic plating layer (10b) of the first conductor layer 10 to the second conductor layer 30. In FIG. 1, the via conductor 40 connects the electrolytic plating layer (10b) of the pad 14 to the land 36. The via conductor 40 is formed of a seed layer (30a) and an electrolytic plating layer (30b) on the seed layer (30a).

Each side of the printed wiring board 2 illustrated in FIG. 1 has a length of 50 mm or more. The length of each side is preferably 100 mm or more. The length of each side is 250 mm or less.

### Method for Manufacturing Printed Wiring Board

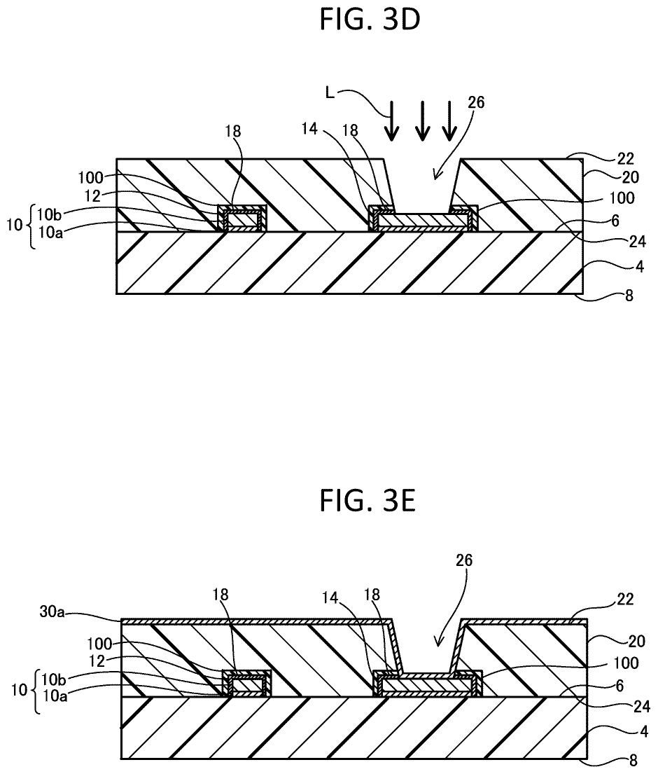

FIGS. 3A-3E illustrate a method for manufacturing the printed wiring board 2 of the embodiment. FIGS. 3A-3E are cross-sectional views. FIG. 3A illustrates the insulating layer 4 and the first conductor layer 10 formed on the third surface 6 of the insulating layer 4. The first conductor layer 10 is formed using a semi-additive method. The first conductor layer 10 is formed by a seed layer (10a) on the third surface 6 and an electrolytic plating layer (10b) on the seed layer (10a).

The surface of the first conductor layer 10 is roughened. After that, the surface of the first conductor layer 10 is oxidized. As illustrated in FIG. 3B, the copper oxide film 18 is formed on the surface of the first conductor layer 10. The oxidizing of the surface of the first conductor layer 10 is performed, for example, by heating an intermediate substrate illustrated in FIG. 3A in an oxygen atmosphere or in the air. The heating temperature is, for example, 100° C. or higher and 150° C. or lower. The heating time is, for example, 20 seconds or higher and 30 seconds or lower. The thickness and composition of the copper oxide film 18 can be adjusted by adjusting the heating temperature and heating time. A mixed gas containing oxygen and nitrogen may be used as a gas for forming the copper oxide film 18.

As illustrated in FIG. 3C, the adhesive layer 100 is formed on the upper and side surfaces of the first conductor layer 10. For example, the adhesive layer 100 is formed by immersing the intermediate substrate illustrated in FIG. 3B in a chemical solution containing a nitrogen-based organic compound. The chemical solution has a pH of 7 or less. By immersing the intermediate substrate in the chemical solution, the adhesive layer 100 including the smoothing film 110 and the protruding parts 120 is formed on the upper and side surfaces of the first conductor layer 10. The adhesive layer 100 is formed on the copper oxide film 18. In a modified example, the adhesive layer 100 is formed by applying a chemical solution on the first conductor layer 10. When the adhesive layer 100 is formed, the intermediate substrate is taken out from the chemical solution. The adhesive layer 100 is dried. The upper surface of the adhesive layer 100 before the drying may be smooth. In this case, by the drying, a part of the adhesive layer aggregates. By the aggregating, the adhesive layer 100 including the smooth film 110 and the protruding parts 120 is formed.

The resin insulating layer 20 is formed on the first conductor layer 10 which is covered by the adhesive layer 100. The second surface 24 of the resin insulating layer 20 faces the third surface 6 of the insulating layer 4. The second surface 24 is in contact with the adhesive layer 100. As illustrated in FIG. 3D, laser (L) is irradiated from above the resin insulating layer 20. The laser (L) penetrates the resin insulating layer 20. The laser (L) removes the adhesive layer 100 covering the pad 14 and the copper oxide film 18 on the surface of the pad 14. The opening 26 penetrates the resin insulating layer 20, the adhesive layer 100, and the copper oxide film 18 to reach the electrolytic plating layer (10b). A bottom of the opening 26 is formed by the electrolytic plating layer (10b) of the pad 14. The electrolytic plating layer (10b) of the pad 14 is exposed from the opening 26. The laser (L) is, for example, UV laser or CO₂ laser.

The inside of the opening 26 is cleaned. Resin residues generated when the opening 26 is formed are removed. The cleaning of the inside of the opening 26 is performed using plasma. That is, the cleaning is performed by a dry process. In the embodiment, the cleaning can be performed using a chemical solution containing an oxidizing agent. An example of the oxidizing agent is potassium permanganate. The cleaning includes a desmear treatment. The adhesive layer 100 formed between the second surface 24 of the resin insulating layer 20 and the pad 14 is not removed. Therefore, no gap is formed between the second surface 24 of the resin insulating layer 20 and the pad 14.

As illustrated in FIG. 3E, the seed layer (30a) is formed on the first surface 22 of the resin insulating layer 20. The seed layer (30a) is formed by electroless plating. It is also possible that the seed layer (30a) is formed by sputtering.

A plating resist is formed on the seed layer (30a). The plating resist has openings for forming the first signal wiring 32, the second signal wiring 34, and the land 36 (FIG. 1).

The electrolytic plating layer (30b) is formed on the seed layer (30a) exposed from the plating resist. The electrolytic plating layer (30b) is formed of copper. The electrolytic plating layer (30b) fills the opening 26. The first signal wiring 32, the second signal wiring 34, and the land 36 are formed by the seed layer (30a) and the electrolytic plating film (30b) on the first surface 22. The second conductor layer 30 is formed. The via conductor 40 is formed by the seed layer (30a) and the electrolytic plating film (30b) in the opening 26. The via conductor 40 connects the electrolytic plating layer (10b) of the pad 14 to the land 36. The first signal wiring 32 and the second signal wiring 34 form a pair wiring.

The plating resist is removed. The seed layer (30a) exposed from the electrolytic plating layer (30b) is removed. The second conductor layer 30 and the via conductor 40 are formed at the same time. The printed wiring board 2 of the embodiment is obtained.

In the printed wiring board 2 of the embodiment, the surface of the first conductor layer 10 is formed of a film formed of copper oxide (the copper oxide film 18). It is thought that a dipole interaction occurs between the copper oxide film 18 and the adhesive layer 100, strengthening the bond between the first conductor layer 10 and the adhesive layer 100. Therefore, the embodiment can increase the adhesion between the first conductor layer 10 and the resin insulating layer 20. Even when the number of conductor layers in a buildup layer is 5 or more, the resin insulating layer 20 is unlikely to peel off from the first conductor layer 10. Even when the length of each side of the printed wiring board 2 exceeds 50 mm, the resin insulating layer 20 is unlikely to peel off from the first conductor layer 10. Even when the number of via conductors forming a stacked via is 5 or more, the embodiment can suppress a change in resistance caused by peeling. Further, the root mean square roughness (Rq) of the surface of the first conductor layer 10 is 0.23 μm or less. Therefore, when data is transmitted via the conductor circuit included in the first conductor layer 10, transmission loss is small. When a high-speed signal is transmitted, noise is unlikely to occur. The printed wiring board 2 of the embodiment can transmit high-speed signals with low loss and can suppress peeling between the conductor layer and the resin insulating layer. A high quality printed wiring board 2 is provided.

The copper oxide film 18 of the embodiment has a thickness of 10 nm or less. For example, when the thickness of the copper oxide film 18 exceeds 10 nm, distortion is likely to occur within the copper oxide film 18. It is thought that due to the distortion, the copper oxide film 18 is likely to peel off from the electrolytic plating layer (10b). Copper oxide has higher electrical resistance than copper. When the thickness of the copper oxide film 18 exceeds 10 nm, it is thought that the copper oxide film 18 may affect the transmission speed. In the embodiment, since the thickness of the copper oxide film 18 is 10 nm or less, the bond between the first conductor layer 10 and the adhesive layer 100 is strong. The printed wiring board 2 of the embodiment is suitable for high-speed signal transmission.

The copper oxide film 18 of the embodiment contains Cu₂O and CuO, and the Cu₂O content is 90 wt % or more. A main component of the copper oxide film 18 is Cu₂O. Cu₂O is less susceptible to distortion than CuO. The bonding strength between the first conductor layer 10 and the adhesive layer 100 is high.

The adhesive layer 100 of the embodiment is formed of a substantially smooth film 110 and protruding parts 120 protruding from the smooth film 110. The adhesive layer 100 has unevenness formed by the protruding parts 120 and the smooth film 110. The adhesive layer 100 has unevenness formed by the multiple protrusions 122. Therefore, the first conductor layer 10 and the resin insulating layer 20 are sufficiently adhered to each other via the adhesive layer 100.

### First Alternative Example

A printed wiring board 2 of a first alternative example of the embodiment includes multiple conductor layers, multiple interlayer resin insulating layers, and multiple via conductors. The conductor layers and the interlayer resin insulating layers are alternately laminated. Adjacent conductor layers are connected by the via conductors. In the first alternative example, the number of the conductor layers is 5 or more and 20 or less. The surface of each conductor layer is preferably formed of a copper oxide film 18. The interlayer resin insulating layers have substantially equal thicknesses. The conductor layers and the interlayer resin insulating layers can be adhered to each other with adhesive layers 100. In the embodiment and the first alternative example, the adhesive layers 100 have similar structures and shapes. Similar to the embodiment, the adhesive layers 100 are formed on upper and side surfaces of the conductor layers. The adhesive layers 100 are each sandwiched between a conductor layer and an interlayer resin insulating layer. Even when the number of the conductor layers is 5 or more, the interlayer resin insulating layers are unlikely to peel off from the conductor layers. Since the number of the conductor layers is 20 or less, a crack caused by the adhesive layers 100 is unlikely to occur in the interlayer resin insulating layers. The number of the conductor layers is preferably 10 or more. The number of the conductor layers is more preferably 15 or more. The adhesive layers 100 effectively function.

The printed wiring board 2 of FIG. 1 includes two conductor layers (the first conductor layer 10 and the second conductor layer 30). There is one first conductor layer 10. There is one second conductor layer 30. The first conductor layer 10 and the second conductor layer 30 are included in the conductor layers of the first alternative example. The resin insulating layer 20 of FIG. 1 is included in the interlayer resin insulating layers of the first alternative example. In the first alternative example, the conductor layers other than the first conductor layer 10 and the second conductor layer 30 are third conductor layers. In the first alternative example, one of the multiple interlayer resin insulating layers is formed directly on the resin insulating layer 20 and the second conductor layer 30. The interlayer resin insulating layer formed directly on the resin insulating layer 20 and the second conductor layer 30 is a first interlayer resin insulating layer. In the first alternative example, an adhesive layer 100 is formed between the first interlayer resin insulating layer and the second conductor layer 30. Or, no adhesive layer 100 is formed between the first interlayer resin insulating layer and the second conductor layer 30. The conductor layers of the first alternative example and the first conductor layer 10 of the embodiment are similar. The two have similar root mean square roughnesses (Rq).

### Second Alternative Example

In a second alternative example, a conductor layer is formed below the insulating layer 4 of the printed wiring board 2 of FIG. 1. And, the insulating layer 4 is formed by the resin insulating layer 20 of FIG. 1. The conductor layer and the first conductor layer 10 are connected by a via conductor penetrating the resin insulating layer sandwiched between the conductor layer and the first conductor layer 10. Except for forming the conductor layer below the insulating layer 4, forming the insulating layer 4 by the resin insulating layer 20, and forming the via conductor in the resin insulating layer sandwiched between the conductor layer and the first conductor layer 10, the embodiment and the second alternative example are similar. The conductor layers of the second alternative example and the first conductor layer 10 of the embodiment are similar. The surface of each conductor layer of the second alternative example is preferably formed of a copper oxide film 18. The two have similar root mean square roughnesses (Rq).

Japanese Patent Application Laid-Open Publication No. 2001-203462 describes a method for manufacturing a multilayer printed wiring board, the method including: sequentially laminating a conductor circuit and an interlayer resin insulating layer on a substrate; and forming a layer containing a triazine compound on at least a part of a surface of the conductor circuit. The conductor circuit and the interlayer resin insulating layer are adhered to each other via a layer containing a triazine compound.

In the printed wiring board manufactured using the technology of Japanese Patent Application Laid-Open Publication No. 2001-203462, it is thought that the upper and side surfaces of the conductor circuit are not roughened for high-speed signal transmission. Therefore, when a large stress is applied between the conductor circuit and the interlayer resin insulating layer, peeling is expected to occur between the conductor circuit and the interlayer resin insulating layer. When the number of conductor layers in a build-up layer is 5 or more, peeling is expected to occur between the conductor circuit and the interlayer resin insulating layer. When a length of each side of the printed wiring board exceeds 50 mm, peeling is expected to occur between the conductor circuit and the interlayer resin insulating layer.

A printed wiring board according to an embodiment of the present invention includes: an insulating layer; a first conductor layer formed on the insulating layer; an adhesive layer formed on the first conductor layer; and a resin insulating layer formed on the insulating layer and the first conductor layer. A main component of the first conductor layer is copper, and a surface of the first conductor layer is formed of a copper oxide film.

In a printed wiring board of an embodiment of the present invention, the surface of the first conductor layer is formed of a copper oxide film. It is thought that a dipole interaction occurs between the copper oxide film and the adhesive layer, strengthening the bond between the first conductor layer and the adhesive layer. The embodiment can increase the adhesion between the first conductor layer and the resin insulating layer. Even when the number of conductor layers in a buildup layer is 5 or more, the resin insulating layer is unlikely to peel off from the first conductor layer. Even when the length of each side of the printed wiring board exceeds 50 mm, the resin insulating layer is unlikely to peel off from the first conductor layer. A high quality printed wiring board is provided.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
an insulating layer;
a conductor layer formed on the insulating layer;
an adhesive layer formed on the conductor layer; and
a resin insulating layer formed on the insulating layer such that the resin insulating layer is covering the conductor layer,
wherein the conductor layer includes a main component comprising copper such that the conductor layer includes a copper oxide film forming a surface thereof.

2. The printed wiring board according to claim 1, wherein the conductor layer is formed such that the copper oxide film has a thickness of 10 nm or less.

3. The printed wiring board according to claim 2, wherein the conductor layer is formed such that the thickness of the copper oxide film is 3 nm or more.

4. The printed wiring board according to claim 1, wherein the conductor layer is formed such that the surface of the conductor layer has a root mean square roughness Rq of 0.23 μm or less.

5. The printed wiring board according to claim 4, wherein the conductor layer is formed such that the root mean square roughness Rq of the surface of the conductor layer is 0.1 μm or less.

6. The printed wiring board according to claim 1, wherein the conductor layer is formed such that the copper oxide film includes a main component comprising Cu₂O.

7. The printed wiring board according to claim 6, wherein the conductor layer is formed such that the copper oxide film includes Cu₂O and CuO such that a content of Cu₂O is 90 wt % or more.

8. The printed wiring board according to claim 2, wherein the conductor layer is formed such that the copper oxide film includes a main component comprising Cu₂O.

9. The printed wiring board according to claim 1, further comprising:
a second conductor layer formed on the resin insulating layer; and
a via conductor formed in an opening penetrating through the resin insulating layer such that the via conductor is connecting the conductor layer and the second conductor layer,
wherein the conductor layer includes a seed layer and an electrolytic copper plating layer on the seed layer, and the resin insulating layer is formed such that the opening is penetrating through the copper oxide film of the conductor layer and reaching the electrolytic copper plating layer and that the via conductor is connecting the electrolytic copper plating layer of the conductor layer and the second conductor layer.

10. The printed wiring board according to claim 1, wherein the adhesive layer includes an organic material.

11. The printed wiring board according to claim 1, wherein the adhesive layer has a smooth film part and a protruding part protruding from the smooth film part.

12. The printed wiring board according to claim 2, wherein the conductor layer is formed such that the surface of the conductor layer has a root mean square roughness Rq of 0.23 μm or less.

13. The printed wiring board according to claim 12, wherein the conductor layer is formed such that the root mean square roughness Rq of the surface of the conductor layer is 0.1 μm or less.

14. The printed wiring board according to claim 2, wherein the conductor layer is formed such that the copper oxide film includes a main component comprising Cu₂O.

15. The printed wiring board according to claim 14, wherein the conductor layer is formed such that the copper oxide film includes Cu₂O and CuO such that a content of Cu₂O is 90 wt % or more.

16. The printed wiring board according to claim 3, wherein the conductor layer is formed such that the copper oxide film includes a main component comprising Cu₂O.

17. The printed wiring board according to claim 2, further comprising:
a second conductor layer formed on the resin insulating layer; and
a via conductor formed in an opening penetrating through the resin insulating layer such that the via conductor is connecting the conductor layer and the second conductor layer,
wherein the conductor layer includes a seed layer and an electrolytic copper plating layer on the seed layer, and the resin insulating layer is formed such that the opening is penetrating through the copper oxide film of the conductor layer and reaching the electrolytic copper plating layer and that the via conductor is connecting the electrolytic copper plating layer of the conductor layer and the second conductor layer.

18. The printed wiring board according to claim 2, wherein the adhesive layer includes an organic material.

19. The printed wiring board according to claim 2, wherein the adhesive layer has a smooth film part and a protruding part protruding from the smooth film part.

20. The printed wiring board according to claim 3, wherein the conductor layer is formed such that the surface of the conductor layer has a root mean square roughness Rq of 0.23 μm or less.
